(19) United States
(12) Patent Application Publication
(10) Pub. No.: US 2005/0197076 A1
(43) Pub. Date: Sep. 8, 2005

(54) Radio communication device and control method of amplification circuit thereof

(75) Inventors: Shinji Saito, Kawasaki (JP); Tatsuaki Kitta, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 10/898,251

(22) Filed: Jul. 26, 2004

(30) Foreign Application Priority Data
Mar. 2, 2004 (JP) 2004-057846

(51) Int. Cl. H04B 1/02; H03C 1/52; H04B 1/04; H01Q 11/12

(52) U.S. Cl. 455/108; 375/300

(57) ABSTRACT

In a radio communication device which generates a baseband signal based on inputted transmit data, then modulates the baseband signal to a modulating signal, amplifies the modulating signal in a modulating circuit, and transmits the amplified modulating signal, a modulating signal control circuit which detects an amplitude of the modulating signal based on a digital baseband signal before DA conversion processing generated in a baseband processing circuit and controls a dynamic range of the amplification circuit based on a result of the detection is provided, and consequently, the amplification circuit can be properly controlled according to the state of a transmit signal by a simple circuit configuration.

### CROSS-REFERENCE TO RELATED APPLICATIONS

This application is based upon and claims the benefit of priority from the prior Japanese Patent Application No. 2004-057846, filed on Mar. 2, 2004, the entire contents of which are incorporated herein by reference.

### BACKGROUND OF THE INVENTION

1. Field of the Invention

The present invention relates to a radio communication device and a control method of an amplification circuit thereof, and more particularly relates to a control system of a transmitting amplification circuit.

2. Description of the Related Art

FIG. 10A shows the configuration of a conventional radio communication device with amplitude modulation.

In the radio communication device shown in FIG. 10A, a baseband processing circuit 101 subjects transmit data inputted from a digital processing circuit or the like not shown to predetermined processing to generate a baseband signal BSC and outputs the baseband signal BSC to a transmitting IF/RF circuit 102. The baseband signal BSC is subjected to modulation processing and frequency conversion processing from an IF (intermediate frequency) signal to an RF (radio frequency) signal in the transmitting IF/RF circuit 102 and outputted as a modulating signal TSC. The modulating signal TSC is transmitted from an antenna 104 via a switch 107 after being amplified in an amplification circuit 103 called a power amplifier (PA).

On the other hand, a signal received by the antenna 104 is frequency-converted from an RF signal to an intermediate frequency (IF) baseband signal in a receiving IF/RF circuit 106 after being amplified in an amplification circuit 105 called a low noise amplifier (LNA) via the switch 107. The baseband signal outputted from the receiving IF/RF circuit 106 is converted into digital data in the baseband processing circuit 101 and outputted to the digital processing circuit or the like not shown.

In the aforementioned conventional radio communication device, when the output power of a transmit signal is determined, as shown in FIG. 10B, the transmit signal is amplified in the amplification circuit (PA) 103 having an always constant dynamic range (compression point) PARC and outputted irrespective of the amplitude of the modulating signal TSC. In FIG. 10B, the horizontal axis shows time and the vertical axis shows voltage level.

The dynamic range performance of the amplification circuit 103 is set to match the worst condition so that no distortion occurs to the transmit signal transmitted from the antenna 104 even when the amplitude of the modulating signal TSC becomes maximum.

Meanwhile, a reduction in size and a reduction in power consumption are strongly required for a recent radio communication device. Therefore, the radio communication device needs to operate its respective constituent circuits under their optimal conditions without any waste according to an operating state and a signal sate. The aforementioned conventional radio communication device uses an amplification circuit which fits a maximum amplitude of the modulating signal TSC, whereby power consumption of the amplification circuit excessively increases depending on the operating state and the signal state.

One of radio communication devices in which the aforementioned problem is improved is a radio communication device which controls the dynamic range of an amplification circuit according to the output power of a transmit signal although the dynamic range is constant with respect to the amplitude of the modulating signal TSC as shown in FIG. 11 (See Patent Document 1, for example).

FIG. 11 is a diagram showing the relation between the modulating signal TSC and the dynamic range PARC of the amplification circuit in this radio communication device. In FIG. 11, the horizontal axis shows time and the vertical axis shows voltage level. In this radio communication device, the dynamic range PARC of the amplification circuit is set small during a period T101 when the output power of the transmit signal is small (for example, the output power is 100 mW). During a period T102 when the output power is large (for example, the output power is 200 mW), the dynamic range PARC of the amplification circuit is set larger than the dynamic range PARC during the period T101. By controlling the dynamic range of the amplification circuit according to the output power of the transmit signal as described above, power consumption can be reduced as compared with the radio communication device shown in FIG. 10A and FIG. 10B.

An example of a radio communication device which realizes a further reduction in power consumption is a radio communication device which controls the dynamic range of an amplification circuit according to a vector length of the modulating signal TSC (See Patent Document 2, for example). In a radio communication device disclosed in the Patent Document 2, after transmit data is converted into an analog signal (analog multilevel signal), the dynamic range of an amplification circuit is controlled according to a vector length at each signal point of the analog multilevel signal, resulting in a great reduction in the power consumption of the amplification circuit.

(Patent Document 1)

Japanese Patent Application Laid-open No. 2000-332622

(Patent Document 2)

Japanese Patent Application Laid-open No. Hei 3-179926

### SUMMARY OF THE INVENTION

An object of the present invention is to make it possible to properly control an amplification circuit of a radio communication device according to the state of a transmit signal by a simple circuit configuration.

A radio communication device of the present invention comprises: a baseband processing circuit generating an analog baseband signal based on inputted digital transmit data; a modulation circuit generating a modulating signal on the basis of the analog baseband signal; an amplification circuit amplifying and outputting the modulating signal; and a control circuit controlling the amplification circuit. The control circuit detects an amplitude of the modulating signal based on a digital baseband signal before the digital baseband signal undergoes digital-analog conversion processing in the baseband processing circuit and controls a dynamic range of the amplification circuit based on a result of the detection.

According to the present invention, the dynamic range of the amplification circuit which amplifies the modulating signal can be controlled according to the amplitude of the modulating signal detected based on the digital baseband signal before digital-analog conversion processing without the necessity of performing analog-digital conversion processing and the like.

### BRIEF DESCRIPTION OF THE DRAWINGS

FIG. 1 is a block diagram showing a configuration example of a radio communication device according to an embodiment of the present invention;

FIG. 2 is a diagram showing the relation between an amplitude of a modulating signal and a dynamic range of an amplification circuit in the radio communication device in this embodiment;

FIG. 3 is a block diagram showing a configuration example of a baseband processing circuit;

FIG. 4 is a block diagram showing a configuration example of a modulating signal control circuit;

FIG. 5 is a diagram showing a concrete configuration example of an arithmetic circuit;

FIG. 6A is a diagram showing a concrete configuration example of a maximum value detecting circuit, and FIG. 6B is a timing chart of the operation of the maximum value detecting circuit;

FIG. 7A and FIG. 7B are diagrams showing a concrete configuration example of a PA control signal generating circuit;

FIG. 8A and FIG. 8B are diagrams for explaining the operation of the baseband processing circuit;

FIG. 9A to FIG. 9D are diagrams showing configuration examples of the amplification circuit which is controllable by a PA control signal;

FIG. 10A and FIG. 10B are diagrams showing a conventional radio communication device; and

FIG. 11 is a diagram showing another control example of a dynamic range of an amplification circuit in the conventional radio communication device.

### DETAILED DESCRIPTION OF THE PREFERRED EMBODIMENTS

However, in the radio communication device disclosed in the Patent Document 2, processing for finding a vector length at each signal point from the analog multilevel signal and generating a bias control signal which controls the power of the amplification circuit according to the vector length is performed by digital processing. Accordingly, an element for AD conversion to convert the analog multilevel signal into digital data is needed.

Moreover, the timing in which the analog multilevel signal is modulated in a modulator and supplied to the amplification circuit and the timing in which the bias control signal corresponding to the analog multilevel signal generated in the control circuit is supplied to the amplification circuit need to match, that is, the timing in which each signal is inputted to the amplification circuit needs to be taken into consideration. Here, the time required for AD conversion processing and bias control signal generating processing when the bias control signal is generated is generally longer than the time required for the modulation processing of the analog multilevel signal in the modulator. Accordingly, on the modulation processing side of the analog multilevel signal, a delay circuit element or the like becomes necessary for adjustment of timing with the corresponding bias control signal.

As described above, in the radio communication device disclosed in the Patent Document 2, an extra circuit element needs to be added, which causes a problem that the circuit configuration becomes complicated.

An embodiment of the present invention will be described below based on the drawings.

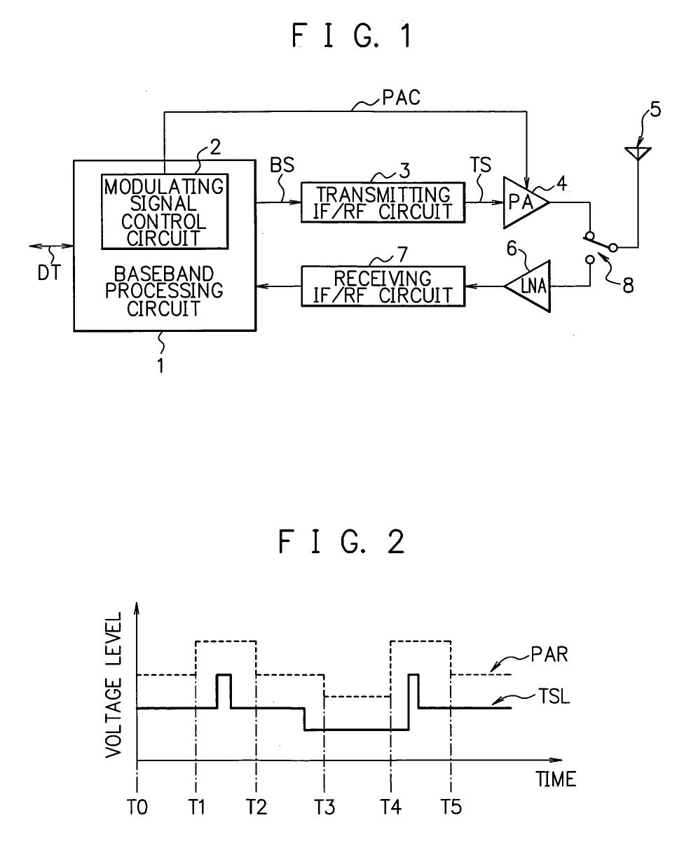

FIG. 1 is a block diagram showing a configuration example of a radio communication device according to the embodiment of the present invention.

The radio communication device in this embodiment includes a baseband processing circuit 1 with a modulating signal control circuit 2 therein, a transmitting IF/RF circuit 3, an amplification circuit 4, an antenna 5, an amplification circuit 6, a receiving IF/RF circuit 7, and a switch circuit 8.

The baseband processing circuit 1 subjects an inputted signal to baseband processing. More specifically, the baseband processing circuit 1 subjects digital data DT (transmit data) inputted from a data processing circuit or the like not shown to predetermined processing to generate a baseband signal BS and outputs it to the transmitting IF/RF circuit 3. Moreover, the baseband processing circuit 1 subjects a baseband signal inputted from the receiving IF/RF circuit 7 to predetermined processing to covert it into digital data and outputs this digital data DT to the data processing circuit or the like not shown.

The modulating signal control circuit 2 generates a PA control signal PAC based on the baseband signal before DA (digital-analog) conversion processing in the baseband processing circuit 1, that is, based on the digital baseband signal, and outputs the generated PA control signal PAC to the amplification circuit 4. The generation and output of the PA control signal PAC in the modulating signal control circuit 2 are performed with respect to each symbol which is a processing unit of transmit/receive signals in the radio communication device (the time is previously determined).

Incidentally, the details of the baseband processing circuit 1 and modulating signal control circuit 2 will be described later.

The transmitting IF/RF circuit 3 performs modulation processing and converts an intermediate frequency (IF) signal into a radio frequency (RF) signal, and it is composed of an amplification circuit and a mixer circuit which performs frequency conversion. The transmitting IF/RF circuit 3 subjects the inputted baseband signal BS to modulation processing and frequency conversion and outputs it as a modulating signal TS to the amplification circuit 4.

The amplification circuit 4 is an amplification circuit called a power amplifier (PA), and it amplifies the modulating signal TS outputted from the transmitting IF/RF circuit 3 and outputs transmit power. The dynamic range of the amplification circuit 4 is controlled according to the PA control signal PAC supplied from the modulating signal control circuit 2.

The amplification circuit 6 is an amplification circuit called a low noise amplifier (LNA), and it amplifies a receive signal (radio frequency signal) received by the antenna 5 and outputs it to the receiving IF/RF circuit 7.

The receiving IF/RF circuit 7 converts a radio frequency (RF) signal into an intermediate frequency (IF) signal, and it is composed of a mixer circuit which performs frequency conversion and so on.

When the digital data DT is inputted from the data processing circuit or the like not shown to the baseband processing circuit 1 in the radio communication device shown in FIG. 1, the digital data is subjected to the predetermined processing in the baseband processing circuit 1, thereafter subjected to DA conversion processing, and outputted as the analog baseband signal BS. On this occasion, the PA control signal PAC is generated on a symbol-by-symbol basis based on the digital baseband signal before DA conversion processing by the modulating signal control circuit 2 in the baseband processing circuit 1 and outputted.

The analog baseband signal BS outputted from the baseband processing circuit 1 is modulated to the modulating signal TS according to the frequency band of a prescribed transmit signal by being subjected to processing such as up-conversion in the transmitting IF/RF circuit 3. After being amplified in the amplification circuit (PA) 4, it is transmitted from the antenna 5 via the switch circuit 8.

On the other hand, when being received by the antenna 5, a receive signal is supplied to the amplification circuit (LNA) 6 via the switch circuit 8 and amplified. The receive signal amplified by the amplification circuit (LNA) 6 is outputted as the data DT to the data processing circuit or the like not shown after the frequency thereof is converted by down-conversion in the receiving IF/RF circuit 7 and then subjected to predetermined processing and converted into digital data in the baseband processing circuit 1.

In the radio communication device in this embodiment, when the modulating signal TS is amplified in the amplification circuit (PA) 4 in a transmit operation, the amplification circuit (PA) 4 is controlled by the PA control signal PAC outputted from the modulating signal control circuit 2 and its dynamic range is controlled as shown in FIG. 2.

FIG. 2 is a diagram showing the relation between an amplitude TSL of the modulating signal TS and a dynamic range PAR of the amplification circuit (PA) 4 in the radio communication device in this embodiment. In FIG. 2, the horizontal axis shows time and the vertical axis shows voltage level. Points in time T0, T1, T2, T3, T4, and T5 each show a time boundary of a symbol which is a processing unit of transmit/receive signals, and a period between a point in time Ti and a point in time T(i+1) (i is a subscript, i=an integer between 0 and 4) corresponds to one symbol.

As shown in FIG. 2, in this embodiment, a maximum value of the amplitude (modulation amplitude of the transmit signal) TSL of the modulating signal TS during a period corresponding to one symbol is detected, and the dynamic range PAR of the amplification circuit (PA) 4 during the period is controlled according to the maximum value. For example, when the maximum value of the amplitude TSL of the modulating signal TS is large as in the periods between the points in time T1 and T2, and T4 and T5 in FIG. 2, the dynamic range PAR is widened, and when the maximum value of the amplitude TSL is small as in the period between the points in time T3 and T4, the amplification circuit (PA) 4 is controlled by the PA control signal PAC so that the dynamic range PAR is narrowed.

The baseband processing circuit 1 previously knows at what time and how the modulating signal TS is generated next, that is, in which period and with how much modulation amplitude TSL the signal is outputted (its details will be described later). In this embodiment, by utilizing this fact, the PA control signal PAC to control the amplification circuit (PA) 4 is generated in advance in the modulating signal control circuit 2 in the baseband processing circuit 1 before the modulating signal TS to be transmitted is inputted to the amplification circuit (PA) 4, whereby, when the modulating signal TS is transmitted, the dynamic range of the amplification circuit (PA) 4 can be properly controlled according to the state of the transmit signal. Moreover, by generating the PA control signal PAC by digital processing with the baseband signal before DA conversion processing in the baseband processing circuit 1, it becomes unnecessary to provide a redundant circuit of an element for AD conversion, and consequently the aforementioned function can be realized by a simpler circuit configuration as compared with the conventional art.

Next, the baseband processing circuit 1 and the modulating signal control circuit 2 therein shown in FIG. 1 will be explained in detail. Incidentally, hereinafter, a case where they are applied to a radio communication device which adopts an OFDM (Orthogonal Frequency Division Multiplexing) modulation scheme will be explained as an example, and only the transmit side of the baseband processing circuit 1 will be explained, and the explanation of the receive side thereof is omitted since the receive side can be configured in the same manner as in the conventional art.

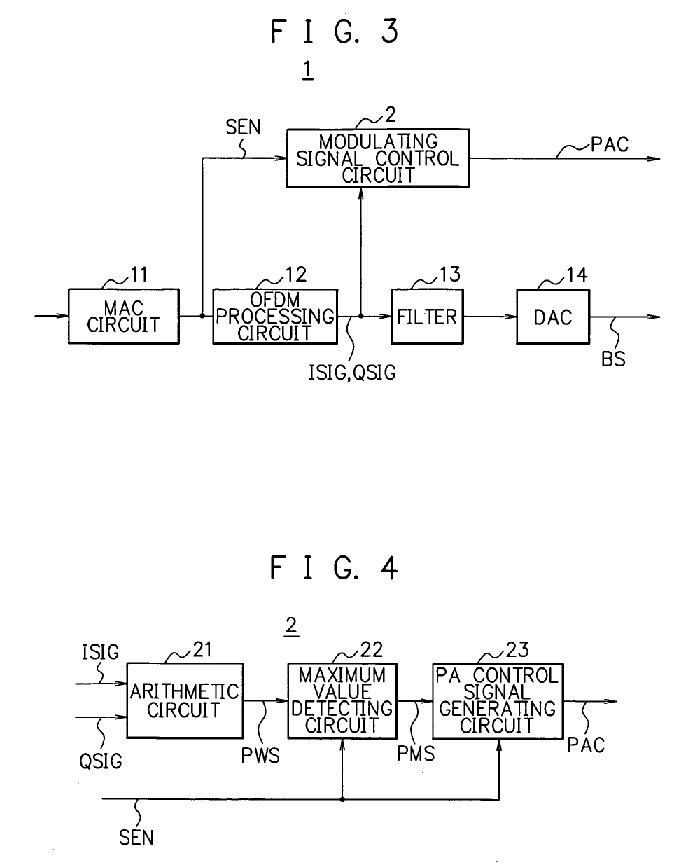

FIG. 3 is a block diagram showing a configuration example of the baseband processing circuit 1.

In FIG. 3, a MAC circuit 11 is a circuit to perform so-called MAC processing. The MAC circuit 11 inputs digital data from the data processing circuit or the like not shown, and outputs the digital data subjected to the predetermined processing to an OFDM processing circuit 12 and at the same time a symbol enable signal SEN which indicates a symbol break to the modulating signal control circuit 2 and the OFDM processing circuit 12.

The OFDM processing circuit 12 subjects the digital data supplied from the MAC circuit 11 to mapping processing in compliance with the OFDM modulation scheme. Moreover, the OFDM processing circuit 12 outputs baseband I channel (Ich) signal (hereinafter referred to only as “I signal”) ISIG and Q channel (Qch) signal (hereinafter referred to only as “Q signal”) QSIG obtained by the mapping processing to the modulating signal control circuit 2 and a filter 13. The I signal ISIG and Q signal QSIG are digital signals.

The filter 13 subjects the I signal ISIG and the Q signal QSIG supplied from the OFDM processing circuit 12 to filter processing and outputs them to a DA converter 14. The DA converter 14 digital-to-analog (DA) converts the digital I signal ISIG and Q signal QSIG supplied from the filter 13 and outputs each of the analog I signal ISIG and Q signal QSIG obtained by the DA conversion as the baseband signal (OFDM modulating signal) BS.

FIG. 4 is a diagram showing a configuration example of the modulating signal control circuit 2 shown in FIG. 1 and FIG. 3.

Incidentally, it is assumed in the following explanation that the I signal ISIG and the Q signal QSIG are each a 10-bit digital signal and that an output of the OFDM processing circuit 12 shown in FIG. 3 is 20 Mbps discrete data.

As shown in FIG. 4, the modulating signal control circuit 2 includes an arithmetic circuit 21, a maximum value detecting circuit 22, and a PA control signal generating circuit 23. The arithmetic circuit 21 and the maximum value detecting circuit 22 constitute an amplitude detecting circuit in the present invention.

The I signal ISIG and the Q signal QSIG supplied from the OFDM processing circuit 12 shown in FIG. 3 are inputted to the arithmetic circuit 21. The arithmetic circuit 21 performs an operation on the amplitude of the modulating signal TS (obtained by modulating the I signal ISIG and the Q signal QSIG) using these inputted signals, and outputs a signal PWS associated with the amplitude of the modulating signal as a result of the operation.

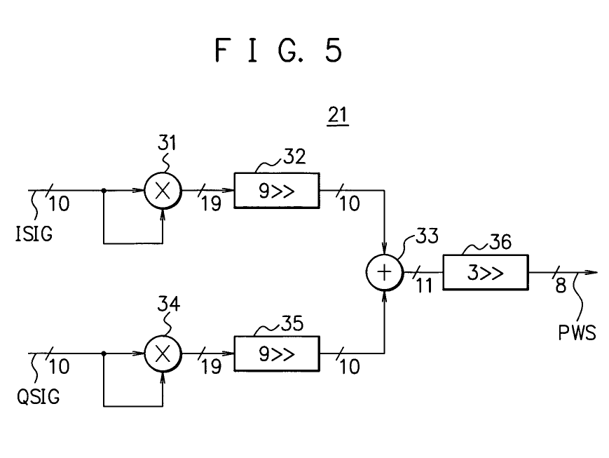

FIG. 5 is a diagram showing the concrete configuration of the arithmetic circuit 21.

The arithmetic circuit 21 is composed of two multipliers 31 and 34, three bit sift circuits 32, 35, and 36, and one adder 33.

The I signal ISIG is supplied to both of two inputs of the multiplier 31, and the multiplier 31 outputs a multiplication result thereof ((I signal)²) to the bit shift circuit 32. Incidentally, a signal outputted as the operation result from the multiplier 31 is 19 bits (with no sign).

The bit shift circuit 32 converts the signal supplied from the multiplier 31 into a 10-bit signal by shifting respective bits of the signal by 9 bits from the MSB (most significant bit) side to the LSB (least significant bit) side and outputs it to the adder 33. In other words, the bit shift circuit 32 extracts only high-order 10 bits of the signal supplied from the multiplier 31 and outputs them to the adder 33.

The multiplier 34 and the bit shift circuit 35 perform the same processing on the Q signal QSIG as the multiplier 31 and the bit shift circuit 32 do, and a result of this processing is outputted to the adder 33. The adder 33 adds the outputs of the bit shift circuits 32 and 35 and outputs a result of the addition to the bit shift circuit 36.

The bit shift circuit 36 converts the signal supplied from the adder 33 into a 8-bit signal (with no sign) by shifting respective bits thereof by 3 bits from the MSB side to the LSB side and outputs it as the output signal PWS.

By this configuration, the arithmetic circuit 21 performs an operation on (I signal)²+(Q signal)² using the supplied I signal ISIG and Q signal QSIG and outputs the output signal PWS corresponding to a value obtained as a result of the operation.

The arithmetic circuit 21 shown in FIG. 5 includes three bit shift circuits 32, 35, and 36, but the arithmetic circuit 21 is not limited to this. If the same operation is performed on the I signal ISIG and the Q signal QSIG, the arithmetic circuit 21 is only required to include at least two multipliers and one adder 33 which adds operation results thereof. Moreover, in place of the bit shift circuit, a circuit having a quantization processing function is also available, and, for example, a divider is also possible (provided that the quantization processing associated with the bit shift circuits 32 and 35 needs to be the same).

Returning to FIG. 4, the signal PWS and the symbol enable signal SEN which indicates a symbol break are inputted to the maximum value detecting circuit 22. The maximum value detecting circuit 22 finds a maximum value of the signal PWS, that is, a maximum value of the amplitude of the modulating signal at every predetermined period (one-symbol period) prescribed by the symbol enable signal SEN, and outputs the found maximum value by the signal PMS.

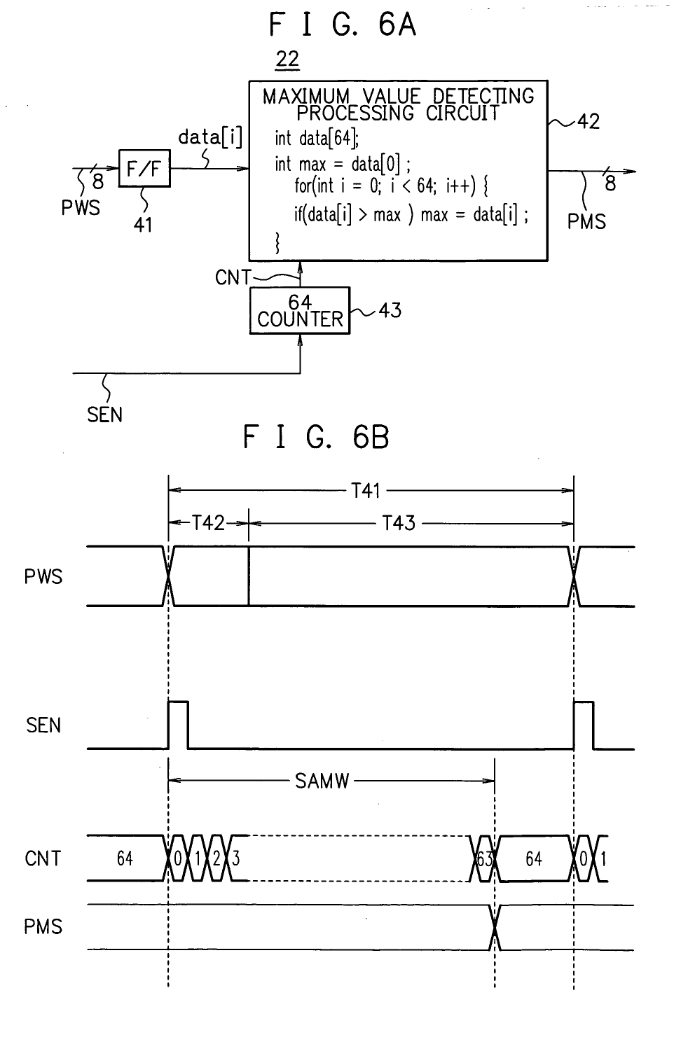

FIG. 6A is a diagram showing the concrete configuration of the maximum value detecting circuit 22.

The maximum value detecting circuit 22 is composed of a flip-flop (FF) 41, a maximum value detecting processing circuit 42, and a counter 43.

The flip-flop 41 inputs the signal PWS (8 bits) and a clock signal not shown and outputs the inputted signal PWS as a signal data [i] to the maximum value detecting processing circuit 42 while synchronizing the inputted signal PWS with the clock signal.

The maximum value detecting processing circuit 42 compares the value of the signal data [i] supplied in sequence from the flip-flop 41 and a maximum value max held therein. The maximum value detecting processing circuit 42 holds the value of the signal data [i] as the new maximum value max when the value of the signal data [i] is larger than the maximum value max. Here, the value of the signal data [i] and the maximum value max are compared every time a counter value CNT supplied from the counter 43 changes. The initial value of the maximum value max is the value of the signal data [i] supplied when the counter value CNT is “0”.

Further, the maximum value detecting processing circuit 42 outputs the held maximum value max as a signal PMS (8 bits) when the counter value CNT becomes “64”.

The counter 43 is a counter circuit in which the counter value CNT is initialized to 0 on the rising edge of the symbol enable signal SEN and incremented by one by the clock signal not shown (provided that the maximum value of the counter value CNT is 64).

FIG. 6B is a timing chart showing the operation of the maximum value detecting circuit 22 shown in FIG. 6A. In FIG. 6B, a period T41 is a one-symbol period (4 μs, for example), a period T42 is a guard interval period (0.8 μs, for example), and a period T43 is a period (3.2 μs, for example) corresponding to a data body. A period SAMW is a period when the operation (comparison) processing is performed in the maximum value detecting processing circuit 42.

As shown in FIG. 6B, the maximum value detecting circuit 22 finds the maximum value out of values of the signal PWS in 64 sampling points (points where the counter value CNT changes) with the rising edge of the symbol enable signal SEN as the base point and outputs the result by the signal PMS. In the one-symbol period T41, this signal PMS makes only one transition after a lapse of the period SAMW and held during the operation processing and after the operation processing in the maximum value detecting processing circuit 42.

Returning to FIG. 4, the PA control signal generating circuit 23 inputs the signal PMS and the symbol enable signal SEN and outputs the PA control signal PAC to control the dynamic range of the amplification circuit (PA) 4 shown in FIG. 1 based on the signal PMS at every symbol period.

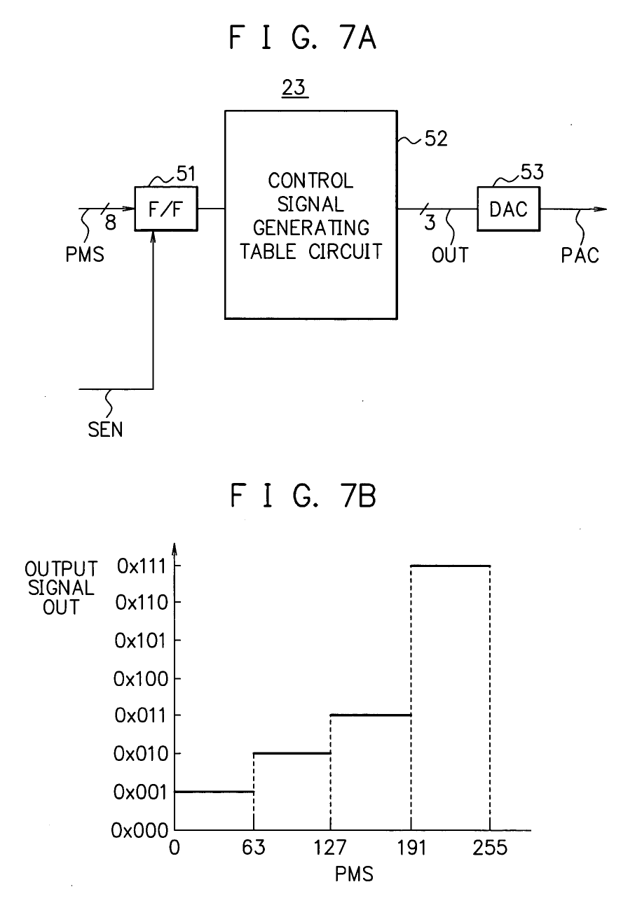

FIG. 7A is a diagram showing the concrete configuration of the PA control signal generating circuit 23.

The PA control signal generating circuit 23 is composed of a flip-flop (FF) 51, a control signal generating table circuit 52, and a DA converter 53.

The flip-flop 51 inputs the signal PMS (8 bits) and the symbol enable signal SEN and outputs the signal PMS to the control signal generating table circuit 52 while synchronizing the signal PMS with the edge of the symbol enable signal SEN.

The control signal generating table circuit 52 converts the inputted signal PMS (8 bits) into a PA control code (3 bits) in accordance with a PA control signal generating table such as shown in FIG. 7B and outputs it. More specifically, the control signal generating table circuit 52 outputs the PA control code of “0x001” when the value indicated by the inputted signal PMS is between 0 and 63, and outputs the PA control code of “0x010” when the value is between 64 and 127. Similarly, it outputs the PA control code of “0x011” when the value indicated by the inputted signal PMS is between 128 and 191, and outputs the PA control code of “0x111” when the value is between 192 and 255. Incidentally, the PA control signal generating table shown in FIG. 7B is an example, and the PA control signal generating table is not limited to this example.

The DA converter 53 DA-converts the output (PA control code) of the control single generating table circuit 52 and outputs it as the PA control signal PAC. Incidentally, the DA converter 53 is provided when the amplification circuit (PA) 4 shown in FIG. 1 is analog controlled. When the amplification circuit (PA) 4 is digital controlled, the DA converter 53 need not be provided, and such a configuration that the number of bits of the output (PA control code) of the control signal generating table circuit 52 and the number of bits for digital controlling the amplification circuit (PA) 4 match is only required.

As explained above, the modulating signal control circuit 2 detects the amplitude of the modulating signal TS using the I signal ISIG and the Q signal QSIG supplied from the OFDM processing circuit 12, and obtains the maximum amplitude of the modulating signal TS in the one-symbol period. Then, the modulating signal control circuit 2 outputs the PA control signal PAC to control the dynamic range of the amplification circuit (PA) 4 according to the obtained maximum amplitude.

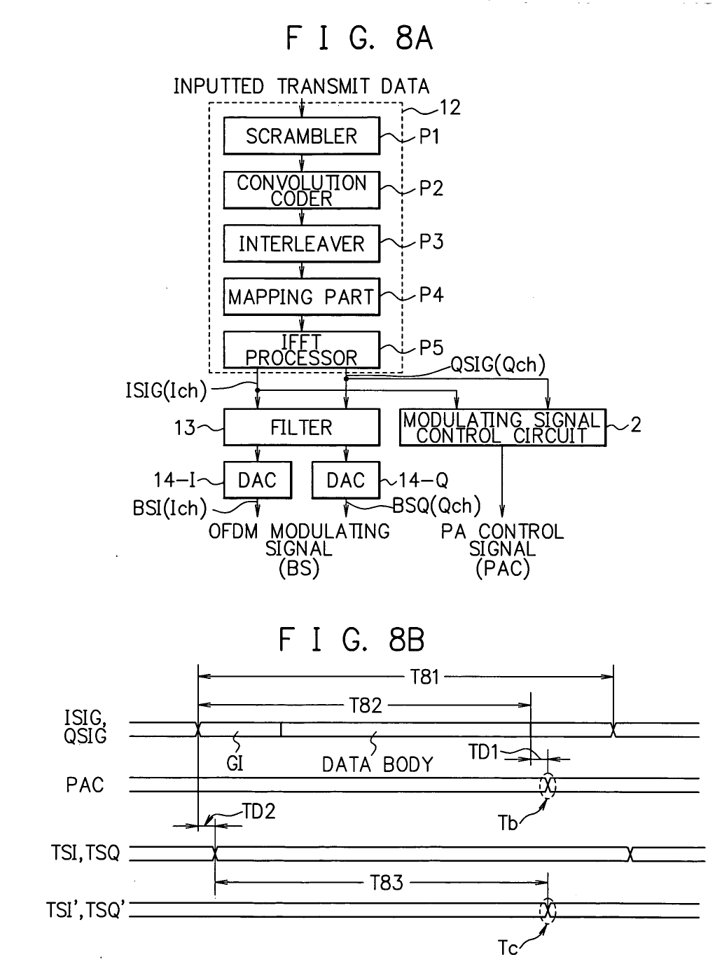

Next, the operation of the baseband processing circuit 1 shown in FIG. 3 will be explained with reference to FIG. 8A and FIG. 8B. FIG. 8A shows the flow of the operation of the baseband processing circuit 1, and FIG. 8B shows a time sequence after the OFDM processing circuit 12 makes an output.

As shown in FIG. 8A, inputted transmit data is inputted to a scrambler P1 and subjected to scramble processing so that unbalanced energy is not generated in the transmit data. The data subjected to the scramble processing is inputted to a convolution coder P2 and subjected to convolution coding processing as pre-processing of error correction. The data subjected to the convolution coding processing is inputted to an interleaver P3, where the data is rearranged.

Subsequently, the data subjected to the interleave processing is inputted to a mapping part P4, and mapped at signal points on an IQ phase plane on a subcarrier-by-subcarrier basis. The data subjected to the mapping processing is inputted to an IFFT (inverse fast Fourier transform) processor P5 and converted from data on a frequency axis to data ISIG and QSIG on a time axis. The data ISIG and QSIG obtained by the IFFT processing are outputted to the filter 13 and the modulating signal control circuit 2.

Here, the processing from the scrambler P1 to the IFFT processor P5 is realized in the OFDM processing circuit 12.

The data ISIG and QSIG supplied to the filter 13 are subjected to oversampling processing in the filter 13 and components (noise) outside the signal band are removed. The data ISIG and QSIG subjected to the oversampling processing are respectively inputted to DA converters 14-1 and 14-Q, converted into analog signals, and thereafter outputted as analog baseband signals (OFDM modulating signals) BSI and BSQ to the transmitting IF/RF circuit 3.

On the other hand, the modulating signal control circuit 2 performs an operation on the amplitude of the modulating signal composed of the data ISIG and QSIG supplied as described above and detects the maximum amplitude in one symbol on a symbol-by-symbol basis. Further, it generates the PA control signal PAC so that the dynamic range of the amplification circuit (PA) 4 becomes optimal based on the detected maximum amplitude of the modulating signal and outputs the PA control signal PAC.

Timing adjustment when the modulating signal TS obtained by subjecting the analog baseband signal (OFDM modulating signal) to modulating processing and the PA control signal PAC are inputted to the amplification circuit (PA) 4 in the radio communication device in this embodiment will be explained with reference to FIG. 8B.

First, a delay associated with the PA control signal PAC will be explained.

A delay by the FF in the modulating signal control circuit 2 corresponds to three stages of the FF as the sum of one stage of the FF in the maximum value detecting circuit 22 and two stages of the FF (one stage in the input side FF 51 and one stage in the DA converter 53) in the PA control signal generating circuit 23. Accordingly, if the modulating signal control circuit 2 is operated by a clock signal with 20 MHz, a delay TD1 corresponding to the three stages of the FF is (1/(20×10⁶)×3)=0.15 μs.

The detection of the maximum value in the maximum value detecting processing circuit 42 is performed by a symbol-by-symbol basis, but it is not necessary to perform the detection all over a one-symbol period T81 (4.0 μs in this case), and the detection can be completed after a period T82 (3.2 μs) as a result of excepting a period corresponding to a guard interval (0.8 μs in this case).

Hence, the PA control signal PAC can be generated and outputted to the amplification circuit (PA) at a point in time Tb just after a lapse of a delay time (T82+TD1=3.35 μs) in the modulating signal control circuit 2 from a point in time when the data ISIG and QSIG are outputted from the OFDM processing circuit 12.

Next, a delay associated with the modulating signal will be explained.

When such a characteristic as can comply with the IEEE802.11a standard is required for the filter 13, an approximately 11-tap interpolation filter which operates by a clock signal which is twice the frequency of a sampling clock signal is used. In this case, a delay in the filter 13 corresponds to six stages of the FF, and if the filter is operated by the clock signal with 40 Mhz, the delay becomes 0.15 μs.

Moreover, if delays in the DA converters 14-1 and 14-Q each correspond to two stages of the FF operated by the clock signal with 40 MHz, the delay becomes 0.05 μs.

Accordingly, it is possible to output modulating signals TSI and TSQ after a lapse of a delay time (TD2=0.2 μs) caused by the filter 13 and the DA converters 14-1 and 14-Q from a point in time when the data ISIG and QSIG are outputted from the OFDM processing circuit 12.

To properly control the dynamic range of the amplification circuit (PA) 4 according to the state of the transmit signal, it is necessary that a change point of the PA control signal PAC and a change point of the modulating signals TSI and TSQ coincide in the amplification circuit (PA) 4. In other words, the modulating signals TSI and TSQ are delayed by a period T83 so that the change point (Tb) of the PA control signal and a change point (Tc) of the delayed modulating signals TSI′ and TSQ′ coincide, and supplied to the amplification circuit (PA) 4. It is possible to realize this delay corresponding to the period T83 by providing a shift register or the like on the output stage side of the filter 13 with consideration given to a propagation delay of the signal in the transmitting IF/RF circuit 3 and a reaction time in the amplification circuit (PA) 4.

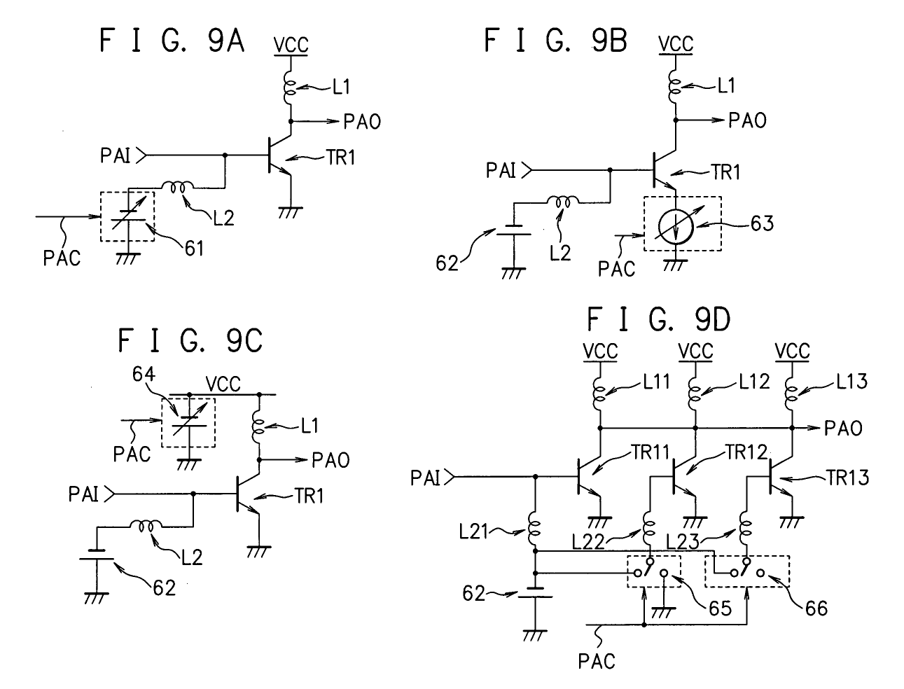

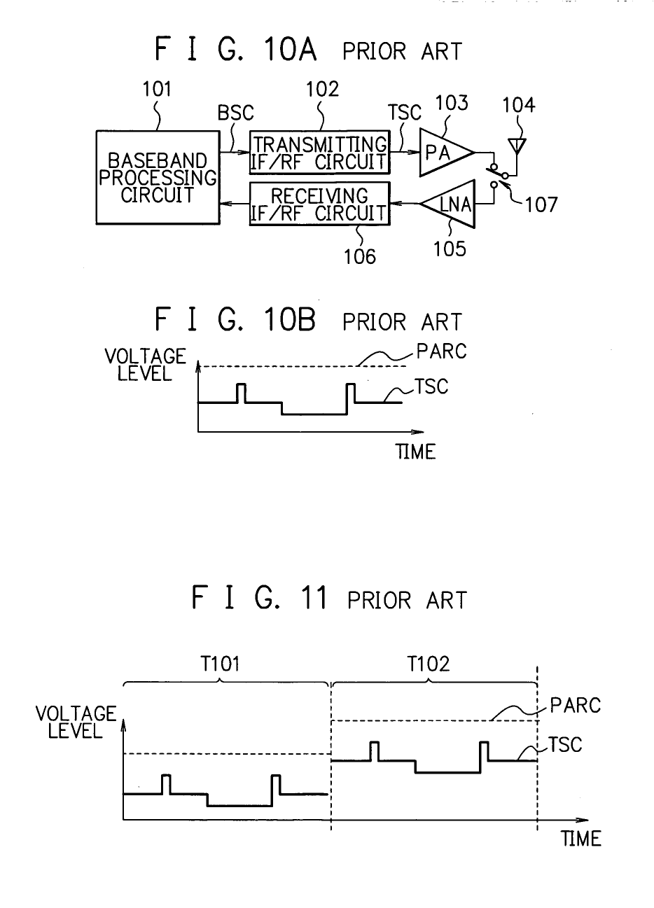

Configuration examples of the amplification circuit (PA) 4 of the radio communication device in this embodiment are shown in FIG. 9A to FIG. 9D. The same numerals and symbols are given to components having the same functions in FIG. 9A to FIG. 9D. Moreover, amplification circuits shown in FIG. 9A to FIG. 8C are examples of an analog controlled amplification circuit, and an amplification circuit shown in FIG. 9D is an example of a digital controlled amplification circuit.

The amplification circuit shown in FIG. 9A is composed of one transistor TR1, two coils L1 and L2, and a voltage source 61.

The transistor TR1 has a collector connected to a power supply voltage via the coil L1 and an emitter connected to a ground. An output signal PAO is outputted from between the collector of the transistor TR1 and the coil L1.

In the transistor TR1, an input signal PAI (which corresponds to the modulating signal TS) is supplied to a base. The coil L2 and the voltage source 61 are connected in series between the base of the transistor TR1 and the ground. The PA control signal PAC is supplied to the voltage source 61, and an output voltage of the voltage source 61 is controlled based on the PA Control signal PAC.

In the amplification circuit shown in FIG. 9A, the output voltage of the variable voltage source 61 is controlled based on the PA control signal PAC, and a current flowing through the transistor TR1 and the dynamic range thereof are controlled by changing a bias level (bias voltage) applied to the base of the transistor TR1. More specifically, when the maximum amplitude of the modulating signal TS is large, the bias level of the transistor TR1 is raised by the PA control signal PAC to operate the transistor TR1 so that its dynamic range is widened although its current consumption increases. On the other hand, when the maximum amplitude of the modulating signal TS is small, the bias level of the transistor TR1 is lowered by the PA control signal PAC to operate the transistor TR1 so that its current consumption reduces although its dynamic range is narrowed.

In the amplification circuit shown in FIG. 9B, a constant voltage source 62 is provided in place of the voltage source 61 in the amplification circuit shown in FIG. 9, and a current source 63 which is controlled by the PA control signal PAC is connected between the emitter of the transistor TR1 and the ground.

In the amplification circuit shown in FIG. 9B, the same effect as in the amplification circuit shown in FIG. 9A can be obtained by making the bias level of the transistor TR1 constant and controlling the current source 63 of the transistor TR1 based on the PA control signal PAC.

In the amplification circuit shown in FIG. 9C, the constant voltage source 62 is provided in place of the voltage source 61 in the amplification circuit shown in FIG. 9A, and a voltage source 64 controlled by the PA control signal PAC is connected to a power supply line to which the collector of the transistor TR1 is connected via the coil L1.

In the amplification circuit shown in FIG. 9C, it is possible to control the power consumption and dynamic range of the transistor TR1 by controlling the voltage source 64 based on the PA control signal PAC and changing the power supply voltage applied to the transistor TR1.

In the amplification circuit shown in FIG. 9D, amplification circuits each composed of one transistor TR1k and two coils L1k and L2k (k is a subscript, k=1, 2, or 3) are connected in parallel in multiple stages. The transistor TR1k, the coil L1k, and the coil L2k correspond to the transistor TR1, the coil L1, and the coil L2 shown in FIG. 9A to FIG. 9C.

A base of a transistor TR11 is connected to the voltage source 62 via a coil L21. On the other hand, a base of a transistor TR12 is connected to the voltage source 62 via a coil L22 and a switch 65, and similarly a base of a transistor TR13 is connected to the voltage source 62 via a coil L23 and a switch 66.

The switches 65 and 66 here are used to select whether the bases of the transistors TR12 and TR13 are connected to the voltage source 62 or the ground, and controlled independently based on the PA control signal PAC. For example, the switch 65 is controlled based on the value of the least significant bit of the PA control signal PAC, and the switch 66 is controlled based on the value of the second lower order bit of the PA control signal.

In the amplification circuit shown in FIG. 9D, the same effect as in the amplification circuit shown in FIG. 9A can be obtained by controlling the switches 65 and 66 based on the PA control signal PAC and appropriately selecting the amplification circuit (stage number of the amplification circuit) to be operated.

As explained above, according to this embodiment, the modulating signal control circuit 2 finds the maximum amplitude of the modulating signal TS which is amplified in the amplification circuit (PA) 4 on a symbol-by-symbol basis (at every one-symbol period) based on the digital baseband signal before DA conversion processing which is generated based on the inputted transmit data in the baseband processing circuit 1. Then, in the modulating signal control circuit 2, the control signal to control the dynamic range of the amplification circuit (PA) 4 according to the maximum amplitude is generated to control the amplification circuit (PA) 4.

Therefore, the amplification circuit can be properly and easily controlled according to the amplitude of the modulating signal TS by a simple circuit configuration without providing a redundant circuit such as an element for AD conversion. This makes it possible to control the current flowing through the transistor constituting the amplification circuit (PA) 4 and the dynamic range according to the state of the modulating signal TS and reduce the power consumption in the amplification circuit.

Incidentally, in the aforementioned embodiment, the modulating signal control circuit 2 is provided in the baseband processing circuit 1, but the modulating signal control circuit 2 may be provided independently as long as the aforementioned amplification circuit (PA) 4 can be controlled based on the digital baseband signal before DA conversion processing generated in the basebgand processing circuit 1.

The present embodiment is to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

According to the present invention, an amplification circuit of a radio communication device can be properly controlled according to the state of a transmit signal by a simple circuit configuration without providing an element for AD conversion and the like, and it is possible to reduce the power consumption and control the dynamic range in the amplification circuit according to the state of the transmit signal.

1. A radio communication device, comprising:
a baseband processing circuit generating a digital baseband signal based on inputted digital transmit data and outputting an analog baseband signal obtained by digital-analog conversion of the digital baseband signal;
a modulation circuit generating a modulating signal by performing modulation processing on the basis of the analog baseband signal outputted from said baseband processing circuit;
an amplification circuit amplifying and transmitting the modulating signal generated in said modulation circuit; and
a control circuit detecting an amplitude of the modulating signal based on the digital baseband signal and controlling a dynamic range of said amplification circuit based on a result of the detection.

2. The radio communication device according to claim 1, wherein said control circuit comprises:
an amplitude detecting circuit detecting the amplitude of the modulating signal; and
a control signal generating circuit generating a control signal which controls the dynamic range of said amplification circuit based on a result of the detection in said amplitude detecting circuit and outputting the control signal.

3. The radio communication device according to claim 1, wherein said control circuit detects at every unit period a maximum amplitude of the modulating signal in the unit period and controls the dynamic range of said amplification circuit according to the detected maximum amplitude of the modulating signal.

4. The radio communication device according to claim 3, wherein said control circuit comprises:
an amplitude detecting circuit detecting the maximum amplitude of the modulating signal at the every unit period; and
a control signal generating circuit generating a control signal which controls the dynamic range of said amplification circuit based on a result of the detection in said amplitude detecting circuit.

5. The radio communication device according to claim 4, wherein said amplitude detecting circuit comprises:
an arithmetic circuit calculating the amplitude of the modulating signal based on the digital baseband signal; and
a maximum value detecting circuit detecting the maximum amplitude of the modulating signal based on the amplitude of the modulating signal calculated in said arithmetic circuit.

6. The radio communication device according to claim 4, wherein said control signal generating circuit converts the result of the detection in said amplitude detecting circuit according to a control signal generating table to generate the control signal.

7. The radio communication device according to claim 4, wherein the digital transmit data is modulated in compliance with an OFDM modulation scheme.

8. The radio communication device according to claim 7, wherein said amplitude detecting circuit calculates the amplitude of the modulating signal at any time based on an I signal and a Q signal of the digital baseband signal, extracts the calculated amplitude of the modulating signal at every sampling period for comparison, and detects the maximum amplitude of the modulating signal.

9. The radio communication device according to claim 8, wherein said control signal generating circuit converts information associated with the maximum amplitude of the modulating signal detected in said amplitude detecting circuit according to a control signal generating table to generate the control signal.

10. The radio communication device according to claim 1, wherein said control circuit detects a maximum amplitude of the modulating signal with respect to each symbol which is a processing unit of the digital transmit data, and controls the dynamic range of said amplification circuit according to the detected maximum amplitude of the modulating signal on the symbol-by-symbol basis.

11. The radio communication device according to claim 1, wherein said control circuit controls a bias voltage applied to a base of an output transistor included in said amplification circuit based on the result of the detection in said control circuit.

12. The radio communication device according to claim 1, wherein
said amplification circuit includes an output transistor whose emitter is connected to a reference potential via a current source, and
said control circuit controls the current source based on the result of the detection in said control circuit.

13. The radio communication device according to claim 1, wherein
said amplification circuit includes plural output transistors connected in parallel, and
said control circuit controls the number of the output transistors to be operated based on the result of the detection in said control circuit.

14. A control method of an amplification circuit of a radio communication device, comprising:
a baseband processing step of generating a digital baseband signal based on inputted digital transmit data and outputting an analog baseband signal obtained by digital-analog conversion of the digital baseband signal;
a modulating step of performing modulating processing on the basis of the analog baseband signal to generate a modulating signal;
a control signal generating step of detecting an amplitude of the modulating signal based on the digital baseband signal and generating a control signal which controls a dynamic range of the amplification circuit based on a result of the detection; and
an amplifying step of controlling the amplification circuit according to the control signal, amplifying the modulating signal in the amplification circuit, and outputting the amplified modulating signal.

15. The control method of the amplification circuit of the radio communication device according to claim 14, wherein in said control signal generating step, at every unit period, a maximum amplitude of the modulating signal in the unit period is detected and the control signal is generated based of a result of the detection.

16. The control method of the amplification circuit of the radio communication device according to claim 15, wherein in said control signal generating step, the amplitude of the modulating signal is calculated based on the digital baseband signal, and the maximum amplitude of the modulating signal is detected based on the calculated amplitude of the modulating signal.
